(19) United States
(12) Patent Application Publication
(10) Pub. No.: US 2019/0263125 A1
(43) Pub. Date: Aug. 29, 2019

(54) ATOMIC LAYER DEPOSITION OXIDE LAYERS IN FLUID EJECTION DEVICES

(71) Applicant: HEWLETT-PACKARD DEVELOPMENT COMPANY, L.P., Spring, TX (US)

(72) Inventors: Zhizhang Chen, Corvallis, OR (US); Robert A Pugliese, Corvallis, OR (US); Mohammed S Shaarawi, Corvallis, OR (US)

(73) Assignee: HEWLETT-PACKARD DEVELOPMENT COMPANY, L.P., Spring, TX (US)

(21) Appl. No.: 16/343,501

(22) PCT Filed: Jan. 31, 2016
(86) PCT No.: PCT/US2017/015706

§ 371 Date: Apr. 19, 2019

(51) Int. Cl. B41J 2/16; B33Y 30/00; B29C 64/209; B41J 2/14; C23C 16/34; C23C 16/40; C23C 16/455

(52) U.S. Cl. CPC B41J 2/1642; B33Y 30/00; B29C 64/209; C23C 16/45525; C23C 16/345; C23C 16/405; B41J 2/14016

(57) ABSTRACT

In some examples, to form a fluid ejection device, a thermal resistor is formed on a substrate, a nitride layer is formed over the thermal resistor, and an oxide layer is formed over the nitride layer using atomic layer deposition (ALD) at a temperature greater than 250° Celsius, where the nitride layer and the oxide layer make up a passivation layer to protect the thermal resistor.

### BACKGROUND

A printing system can include a printhead that has nozzles to dispense printing fluid to a print target. In a two-dimensional (2D) printing system, the target is a print medium, such as a paper or another type of substrate onto which print images can be formed. Examples of 2D printing systems include inkjet printing systems that are able to dispense droplets of inks. In a three-dimensional (3D) printing system, the target can be a layer or multiple layers of build material deposited to form a 3D object.

### BRIEF DESCRIPTION OF THE DRAWINGS

Some implementations of the present disclosure are described with respect to the following figures.

FIG. 1 is a sectional view of a fluid ejection die according to some examples.

FIG. 2 is a flow diagram of a process of forming a fluid ejection device, according to some examples.

FIG. 3 is a graph that shows an oxide layer etch rate as a function of atomic layer deposition (ALD) process temperatures, according to some examples.

FIG. 4 is a flow diagram of a process of forming a fluid ejection device, according to further examples.

FIG. 5 is a sectional view of a fluid ejection die according to some examples.

FIG. 6 is a flow diagram of a process of forming a fluid ejection device, according to other examples.

FIG. 7 illustrates a cartridge on which a fluid ejection device according to some examples can be attached.

FIG. 8 illustrates a bar on which a fluid ejection devices according to some examples can be attached.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

### DETAILED DESCRIPTION

In the present disclosure, use of the term “a,” “an”, or “the” is intended to include the plural forms as well, unless the context clearly indicates otherwise. Also, the term “includes,” “including,” “comprises,” “comprising,” “have,” or “having” when used in this disclosure specifies the presence of the stated elements, but do not preclude the presence or addition of other elements.

A printhead for use in a printing system can include nozzles that are activated to cause printing fluid droplets to be ejected from respective nozzles. Each nozzle includes an active ejection element that when activated causes ejection of a droplet of the printing fluid from an ejection chamber in the nozzle. A printing system can be a two-dimensional (2D) or three-dimensional (3D) printing system. A 2D printing system dispenses printing fluid, such as ink, to form images on print media, such as paper media or other types of print media. A 3D printing system forms a 3D object by depositing successive layers of build material. Printing fluids dispensed by the 3D printing system can include ink, as well as fluids used to fuse powders of a layer of build material, detail a layer of build material (such as by defining edges or shapes of the layer of build material), and so forth.

In the ensuing discussion, the term “printhead” can refer generally to an overall assembly that includes multiple printhead dies mounted on a support body, wherein the printhead dies are used to dispense printing fluid towards a target. A printhead can be part a print cartridge that can be removably mounted in a printing system. In other examples, a printhead can be part of a print bar, which can have a width that spans the width of a print target, such as a 2D print medium or a 3D object. In a print bar, the multiple dies of the printhead can be arranged along the width of the print bar. In further examples, a printhead can be mounted on a carriage of a printing system, where the carriage is moveable with respect to a print target.

Although reference is made to a printhead for use in a printing system in some examples, it is noted that techniques or mechanisms of the present disclosure are applicable to other types of fluid ejection devices used in non-printing applications that are able to dispense fluids through nozzles. Examples of such other types of fluid ejection devices include those used in fluid sensing systems, medical systems, vehicles, fluid flow control systems, and so forth.

A type of an active ejection element that can be included in a fluid ejection device for ejecting fluids from the fluid ejection device can include a thermal resistor. A fluid ejection device with multiple nozzles can include respective thermal resistors associated with the corresponding nozzles. A thermal resistor is used to produce heat that vaporizes a fluid contained in a fluid ejection chamber. The vaporization of the fluid in the ejection chamber causes expulsion of a droplet of fluid through the corresponding orifice of a nozzle.

A fluid ejection device can be in the form of a die, on which various thin-film layers can be provided. The thin-film layers can include an electrically resistive layer that can be patterned to form respective thermal resistors. A passivation layer (formed of an electrically insulating material) can be formed to electrically isolate the thermal resistor from fluid in a fluid ejection chamber. Traditional passivation layers can be relatively thick. The presence of a thick passivation layer can increase a turn-on energy of a fluid ejection device, where the turn-on energy is the energy that has to be provided to form a vapor bubble of a size sufficient to eject a specified amount of fluid through an orifice. With a thicker passivation layer between a thermal resistor and a fluid ejection chamber, an increased amount of electrical current and/or an increased voltage would have to be applied to a thermal resistor to produce sufficient turn-on energy to eject fluid from the fluid ejection chamber.

In accordance with some implementations of the present disclosure, a thinner passivation layer can be formed over each thermal resistor of a fluid ejection device, which allows for a reduction of the turn-on energy, such that reduced electrical current and/or reduced turn-on voltage can be applied to activate a nozzle of the fluid ejection device. Reduced turn-on voltage and/or electrical current can also allow for increased activation frequency of a fluid ejection device. With reduced turn-on energy, the temperature in the fluid ejection device can be reduced. Additionally, thinner passivation layers can reduce manufacturing costs for fluid ejection devices.

The thinner passivation layer can be achieved by using atomic layer deposition (ALD) to form an oxide layer in the passivation layer. An oxide layer formed using ALD is referred to as an “ALD oxide layer.” In some examples, use of ALD to form an oxide layer in the passivation layer of a fluid ejection device can also provide enhanced reliability of the fluid ejection device, even though a thinner passivation layer is used. For example, pinhole defects and/or other manufacturing defects of the passivation layer can be avoided or reduced by using the ALD-formed passivation layer according to some implementations. Pinhole defects can be caused by regions of the passivation layer that are not completely formed with the material of the passivation layer. Also, by using ALD to form the oxide layer of the passivation layer, improved step coverage can be achieved during manufacture, where step coverage refers to the ratio of the thickness of a layer at its thinnest to the thickness of the layer formed on an open upper surface.

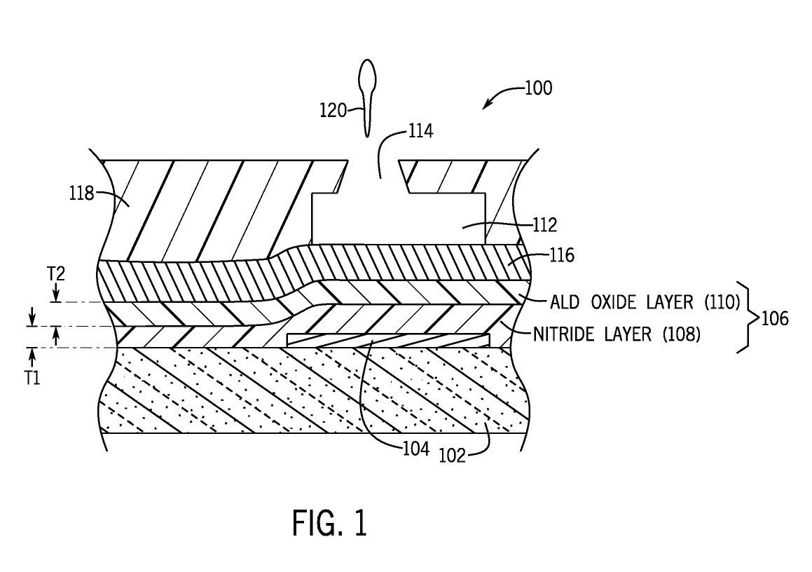

FIG. 1 shows a portion of an example fluid ejection die 100. A “die” can refer to a structure that includes a substrate on which is provided nozzles and control circuitry to control ejection of fluid by the nozzles. The control circuity formed in the fluid ejection die 100 can be used to control activation of thermal resistors.

The fluid ejection die 100 includes various layers. Although a specific arrangement of layers is shown in FIG. 1, it is noted that fluid ejection dies can have other arrangements in other examples.

In the ensuing discussion, reference is made to one layer being formed over another layer. Note that during use, the fluid ejection die 100 can be upside-down from the orientation shown in FIG. 1, such that the term “above” or “on” can actually refer one layer being below another layer in the different orientation, and vice versa. The orientation shown in FIG. 1 can be the orientation of the fluid ejection die 100 during manufacturing of the fluid ejection die 100, as the layers of the fluid ejection die 100 are formed.

The fluid ejection die 100 includes a substrate 102, which can be formed of silicon, another semiconductor material, or another type of material. An electrically resistive layer 104 is formed over the substrate 102. The resistive layer 104 can include a resistive material, such as tungsten silicon nitride, tantalum, aluminum, silicon, tantalum nitride, and so forth. The resistive layer 104 can form a thermal resistor for a corresponding nozzle of the fluid ejection die 100, where the nozzle further includes a fluid ejection chamber 112 and an orifice 114.

During manufacture, the electrically resistive layer 104 deposited over the substrate 102 can be patterned to form respective thermal resistors for corresponding nozzles of the fluid ejection die 100.

A passivation layer 106 is provided over the resistive layer 104. The passivation layer 106 provides protection for the resistive layer 104, by isolating fluid in the fluid ejection chamber 112 from the resistive layer 104. The passivation layer 106 can include electrically insulating materials to electrically isolate the resistive layer 104 from fluid in the fluid ejection chamber 110.

In accordance with some implementations, the passivation layer 106 includes a nitride layer 108 formed over the resistive layer 104, and an oxide layer 110 formed over the nitride layer 108. As used here, a first layer is “over” or “on” a second layer if the first layer is in contact with and above the second layer, or alternatively, the first layer is above the second layer, with an intervening layer (or multiple intervening layers) between the first layer and the second layer.

Although the passivation layer is shown with two layers 108 and 110 in examples according to FIG. 1, it is noted that in other examples, the passivation layer 106 can include more than two layers.

A metal layer 116 can be provided over the passivation layer 106. The metal layer 116 can include tantalum or other metal, and is formed over the passivation layer 106 to add mechanical strength.

As further shown in FIG. 1, a chamber layer 118 is formed over the metal layer 116. The chamber layer 118 can be formed of an epoxy, another polymer, or any other type of material. During manufacturing, etching of the chamber layer 118 can be performed to form the fluid ejection chamber 112 and the orifice 114. Fluid flows from a fluid channel (not shown) to the fluid ejection chamber 112. The orifice 114 leads form the fluid ejection chamber 112 to the outside of the fluid ejection die 100.

Although FIG. 1 shows the fluid ejection chamber 112 and the orifice 114 formed in a monolithic chamber layer 118, it is noted that in other examples, the fluid ejection chamber 112 and the orifice 114 can be formed in respective different layers that are separately processed.

In operation, when the resistive layer 104 is activated (by passing an electrical current through the resistive layer 104 to heat up the resistive layer 104), the heat produced by the resistive layer 104 vaporizes the fluid in the fluid ejection chamber 112, which causes a fluid droplet 120 to be ejected from the orifice 114.

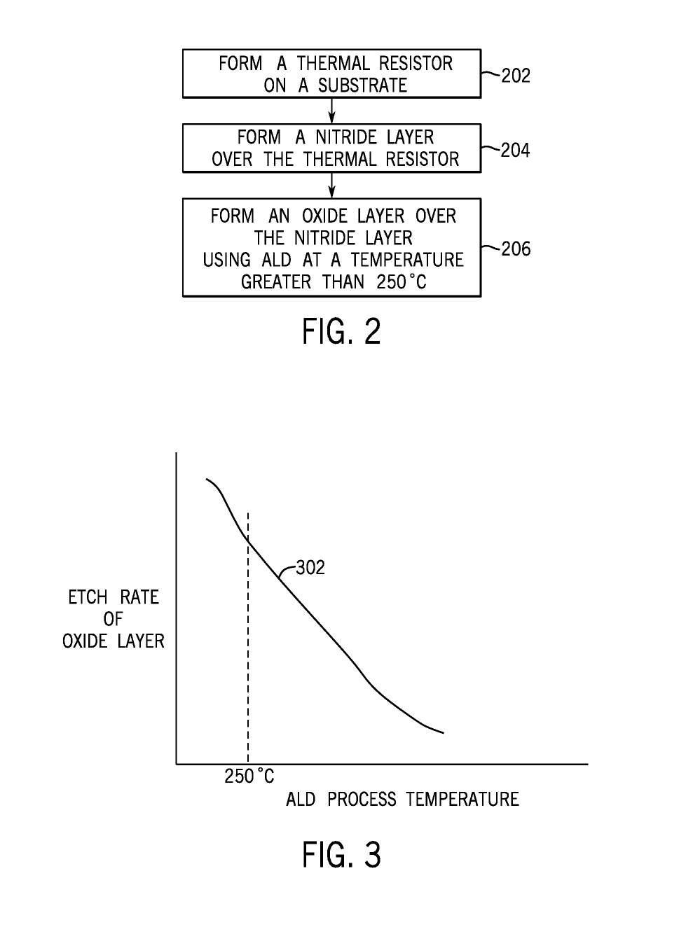

FIG. 2 is a flow diagram of a process of forming a fluid ejection device, such as the fluid ejection die 100 of FIG. 1. The process includes forming (at 202) a thermal resistor on a substrate, such as by forming the resistive layer 104 on the substrate 102 shown in FIG. 1. After the resistive layer is deposited, the resistive layer is patterned to form a thermal resistor (or more specifically, multiple thermal resistors of the fluid ejection device).

Next, the process includes forming (at 204) a nitride layer (e.g., nitride layer 108 in FIG. 1) over the thermal resistor. The nitride layer can provide thermal and chemical stabilization of the resistive layer. The nitride layer can be formed by using a plasma enhanced chemical vapor deposition (PECVD) in some examples. In other examples, other techniques can be used to form the nitride layer. Examples of the nitride layer can include any of the following: silicon nitride, aluminum nitride, titanium nitride, tantalum nitride, niobium oxide, molybdenum nitride, tungsten nitride, and so forth.

Next, the process includes forming (at 206) an oxide layer over the nitride layer using ALD at a temperature greater than 250° Celsius (C). The nitride layer and the oxide layer make up a passivation layer to protect the thermal resistor.

The oxide layer formed using ALD according to some examples can include a metal oxide. Examples of a metal oxide can be selected from among: hafnium oxide, aluminum oxide, titanium oxide, tantalum oxide, magnesium oxide, cesium oxide, niobium oxide, lanthanum oxide, yttrium oxide, aluminum titanium oxide, tantalum hafnium oxide, and so forth.

ALD is used to form a thin layer over an underlying structure. The ALD process involves sequentially applying gas phase chemicals in a repetitive manner to build up the oxide layer. The gas phase chemicals of the ALD process can be referred to as precursors, including a source-material precursor and a binding precursor, which are used alternately and in sequence with inert purge gases introduced between use of the different precursors. The deposited source-material precursor chemically reacts on the surface with the deposited binding precursor to form a single molecular ALD layer. As the ALD process continues, the single molecular ALD layers are built up on a molecular layer-by-molecular layer basis. The final thickness of the ALD layer can be well controlled.

The temperature of the ALD in forming the oxide layer can affect the etch rate associated with the oxide layer. The etch rate of the oxide layer can refer to the rate (expressed as thickness over time) at which the oxide layer is removed in the presence of an etching chemical that is used during manufacture of a fluid ejection device to pattern the oxide layer, such as to form vias for electrical contacts or to form other structures. Examples of an etching chemical can include hydrofluoric oxide, ammonia fluoride, or any other type of chemical that is used to etch layers during manufacture of fluid ejection devices.

As shown in FIG. 3, a curve 302 represents etch rate as a function of ALD process temperature. As depicted by the curve 302, the etch rate of the oxide layer formed using an ALD process decreases as a function of increasing ALD process temperature. As noted above, in some examples, the oxide layer is formed over the nitride layer using ALD at a temperature greater than 250° C. In other examples, the oxide layer is formed using ALD at a temperature greater than 270° C., or at a temperature greater than 280° C., or a temperature greater than 290° C., or at a temperature greater than 300° C. In further examples, the oxide layer is formed using ALD at a temperature of about 300° C. The ALD temperature is at “about” a target temperature if the temperature is within a specified percentage of the target temperature, in this case 300° C., where the specified percentage can be 1%, 2%, 5%, 10%, and so forth.

As depicted in FIG. 3, by increasing the ALD process temperature above 250° C., the etch rate of the oxide layer can be reduced, which means that a smaller amount of the oxide layer is removed as an etching agent is applied to pattern the oxide layer.

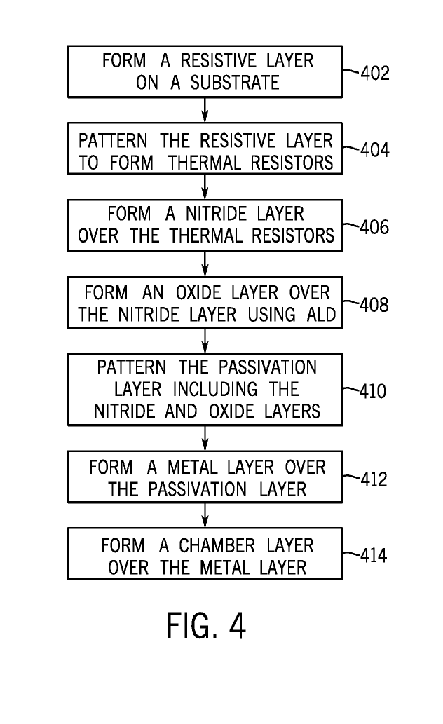

FIG. 4 is a flow diagram of a process of forming a fluid ejection device according to further examples. The process of FIG. 4 includes forming (at 402) a resistive layer on a substrate. The process further includes patterning (at 404) the resistive layer to form respective thermal resistors of the fluid ejection device. The patterning can be performed by using any of various patterning techniques, such as plasma etching and so forth.

The process of FIG. 4 further includes forming (at 406) a nitride layer over the thermal resistors. The process then forms (at 408) an oxide layer using ALD at a higher temperature, such as greater than 250° C.

The process of FIG. 4 further patterns (at 410) the passivation layer including the nitride layer and the oxide layer. Next, process forms (at 412) a metal layer (e.g., the metal layer 116 of FIG. 1) over the passivation layer, and subsequently, the process forms (at 414) a chamber layer (e.g., 118 in FIG. 1) over the metal layer, where chamber layer can be patterned and etched to form fluid ejection chambers and orifices of the fluid ejection device.

As further shown in FIG. 1, the nitride layer 108 can have a thickness T1, and the oxide layer 110 formed using ALD can have a thickness T2. The thickness T1 of the nitride layer 108 can be in the range between 400 angstroms (Å) and 800 Å. Alternatively, the thickness T1 of the nitride layer 108 can be in the range between 400 Å and 600 Å. In some examples, the thickness T2 of the oxide layer can be in the range between a lower thickness of 50 Å and an upper thickness of less than 250 Å. In further examples, the thickness T2 can be in the range between a lower thickness of 100 Å and an upper thickness of less than 200 Å. Although specific thicknesses for T1 and T2 are listed, it is noted that in other examples, different thicknesses can be used.

By using ALD to form the oxide layer 110, the nitride layer 108 can be made to be thinner. As a result, the overall thickness of the passivation layer 106 can be made thinner.

The combined thickness of the passivation layer 106, based on the thickness T1 and T2 of the nitride layer and oxide layer, respectively, is smaller than the thickness of a passivation layer formed using traditional techniques.

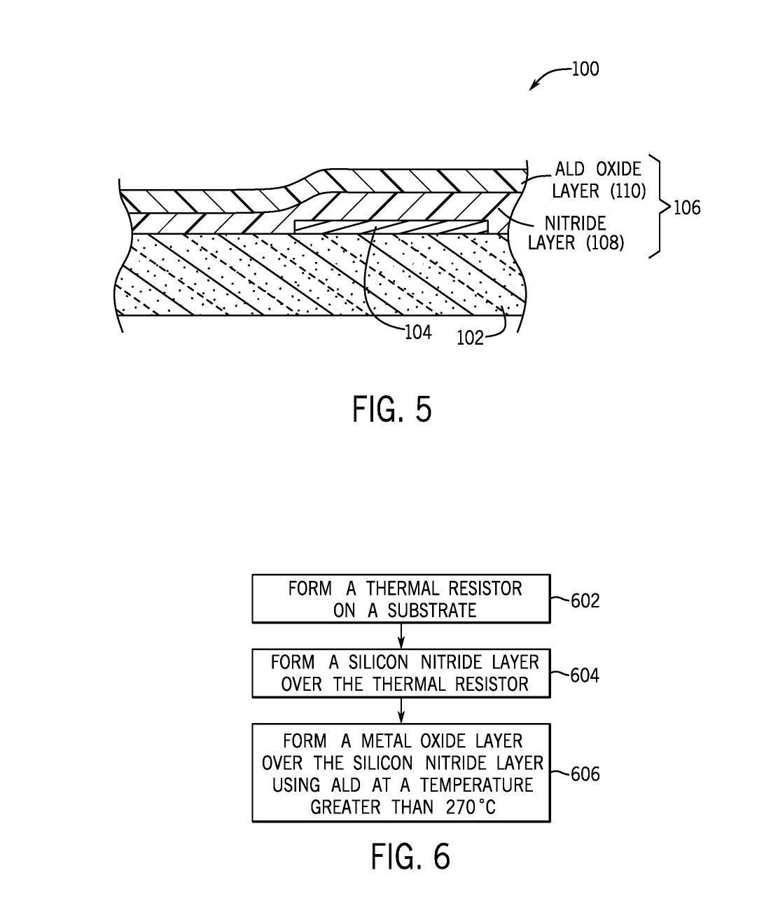

FIG. 5 is a sectional view of a portion of the layers of a fluid ejection device 100 according to some implementations. The layers shown in FIG. 5 are the same as the corresponding layers shown in FIG. 1, except that the metal layer 116 and the chamber layer 118 have been omitted in FIG. 5. The fluid ejection device includes a substrate 102, a thermal resistor (including a resistive layer 104) formed on the substrate 102, and the passivation layer 106 formed over the thermal resistor and including the nitride layer 108 and the ALD oxide layer 110 that has an oxide etch rate of less than 14 A per minute in some examples. In other examples, the ALD oxide layer can have an oxide etch rate, in the presence of an etching chemical (e.g., hydrofluoric oxide, ammonia fluoride, etc.), of less than 10 Å per minute, 8 Å per minute, 5 Å per minute, 4 Å per minute, 2 Å per minute, 1 Å per minute, and so forth. As depicted in FIG. 3, the etch rate of the ALD oxide layer can be reduced by increasing the ALD process temperature when forming the oxide layer.

FIG. 6 is a flow diagram of a process of forming a fluid ejection device according to further implementations. The process of FIG. 6 forms (at 602) a thermal resistor on a substrate. The process forms (at 604) a silicon nitride layer over the thermal resistor. The process further includes forming (at 606) a metal oxide layer over the silicon nitride layer using ALD at a temperature greater than 270° C.

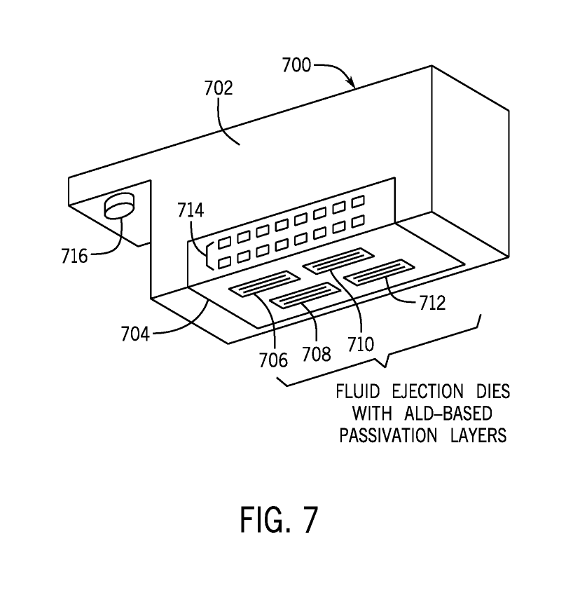

A fluid ejection device (e.g., a printhead) including an ALD-based passivation layer (including an ALD oxide layer) as described herein can be mounted onto a cartridge 700, as shown in FIG. 7. The cartridge 700 can be a print cartridge, for example, which can be removably mounted in a printing system. In other examples, the cartridge 700 can be another type of fluid ejection cartridge removably mounted in other types of systems.

The cartridge 700 has a housing 702 on which a fluid ejection device 704 (e.g., a printhead or printhead die) can be mounted. For example, the fluid ejection device 704 can include a flex cable or other type of thin circuit board that can be attached to an external surface of the housing 702. The fluid ejection device 804 includes fluid ejection dies 706, 708, 710, and 712, each formed using an ALD-based passivation layer.

The fluid ejection device 704 further includes electrical contacts 714 to allow the fluid ejection device 704 to make an electrical connection with another device. In some examples, the cartridge 700 includes a fluid inlet port 716 to receive fluid from a fluid supply that is separate from the cartridge 700. In other examples, the cartridge 700 can include a fluid reservoir that can supply fluid to the die assemblies.

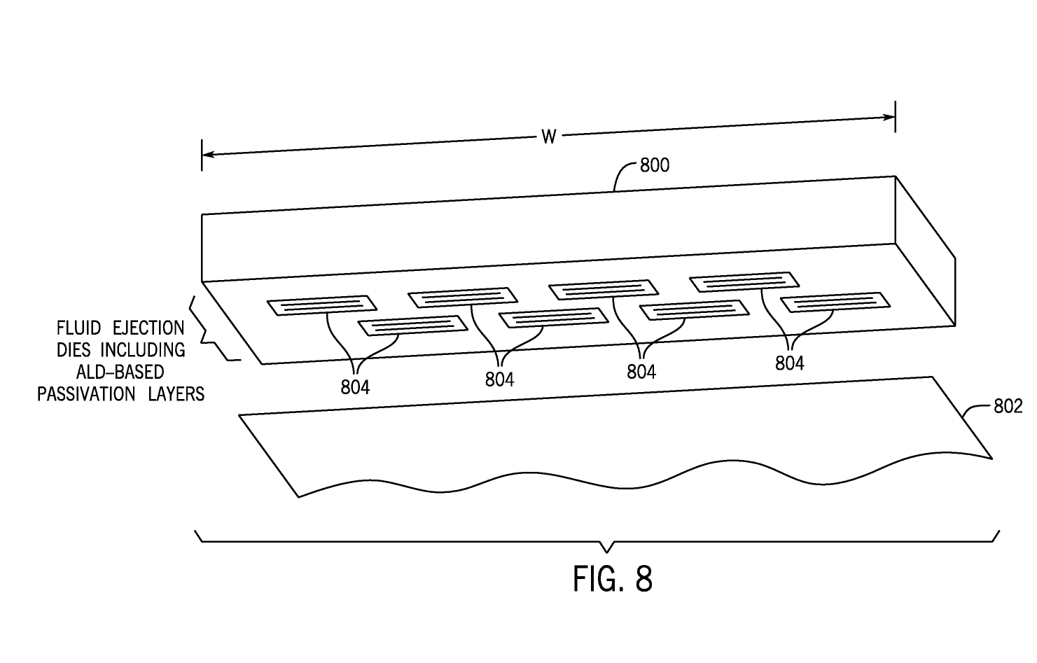

In further examples, a fluid ejection device including an ALD-based passivation layer according to some implementations can be mounted on a bar 800 (e.g., a print bar), such as shown in FIG. 8, where the bar 800 has a width W that allows the bar 800 to cover a width of a target 802 onto which fluids are to be dispensed by fluid ejection dies 804. The fluid ejection dies 804 can include an ALD-based passivation layer.

In further examples, a fluid ejection device (such as a printhead) including an ALD-based passivation layer can be mounted on a carriage that is moveable with respect to a target support structure that supports a target onto which a fluid is to be dispensed by the fluid ejection device.

In the foregoing description, numerous details are set forth to provide an understanding of the subject disclosed herein. However, implementations may be practiced without some of these details. Other implementations may include modifications and variations from the details discussed above. It is intended that the appended claims cover such modifications and variations.

What is claimed is:

1. A method of forming a fluid ejection device, comprising:
forming a thermal resistor on a substrate; and
forming a nitride layer over the thermal resistor; and
forming an oxide layer over the nitride layer using atomic layer deposition (ALD) at a temperature greater than 250° Celsius, the nitride layer and the oxide layer making up a passivation layer to protect the thermal resistor.

2. The method of claim 1, wherein forming the oxide layer uses ALD at a temperature greater than 270° Celsius.

3. The method of claim 1, wherein forming the oxide layer uses ALD at a temperature of about 300° Celsius.

4. The method of claim 1, wherein forming the oxide layer using the ALD comprises forming a metal oxide layer.

5. The method of claim 4, wherein forming the metal oxide layer comprises forming a hafnium oxide layer.

6. The method of claim 5, wherein forming the nitride layer comprises forming a silicon nitride layer.

7. The method of claim 1, wherein forming the oxide layer comprises forming the oxide layer having a thickness in a range between a lower thickness of 50 angstroms and an upper thickness of less than 250 angstroms.

8. The method of claim 7, comprising forming the oxide layer having a thickness in a range between a lower thickness of 100 angstroms and an upper thickness of less than 200 angstroms.

9. The method of claim 7, wherein forming the nitride layer comprises forming the nitride layer having a thickness in a range between 400 angstroms and 800 angstroms.

10. The method of claim 9, comprising forming the nitride layer having a thickness in a range between 400 angstroms and 600 angstroms.

11. The method of claim 1, further comprising forming a chamber layer over the passivation layer, the chamber layer to include a fluid ejection chamber.

12. A fluid ejection device comprising:
a substrate;
a thermal resistor formed on the substrate; and
a passivation layer over the thermal resistor and comprising a nitride layer and an atomic layer deposition (ALD) oxide layer having an oxide etch rate of less than 14 angstroms per minute.

13. The fluid ejection device of claim 12, further comprising a chamber layer over the passivation layer and comprising a fluid ejection chamber and an orifice through which fluid is ejected from the fluid ejection chamber.

14. A method of forming a fluid ejection device, comprising:
forming a thermal resistor on a substrate; and
forming a silicon nitride layer over the thermal resistor; and
forming a metal oxide layer over the silicon nitride layer using atomic layer deposition (ALD) at a temperature greater than 270° Celsius, the silicon nitride layer and the metal oxide layer making up a passivation layer to protect the thermal resistor

15. The method of claim 14, wherein forming the metal oxide layer comprises forming a hafnium oxide layer.
